(19) United States
(12) Patent Application Publication
(10) Pub. No.: US 2018/0182635 A1
(43) Pub. Date: Jun. 28, 2018

(54) FOCUS RING AND SUBSTRATE PROCESSING APPARATUS

(71) Applicant: Tokyo Electron Limited, Tokyo (JP)

(72) Inventors: Toshiya Tsukahara, Miyagi (JP); Junji Ishibashi, Miyagi (JP); Taketoshi Tomioka, Miyagi (JP); Yasuharu Sasaki, Miyagi (JP); Yohei Uchida, Miyagi (JP)

(21) Appl. No.: 15/852,416

(22) Filed: Dec. 22, 2017

(30) Foreign Application Priority Data
Dec. 27, 2016 (JP) 2016-254318
Nov. 22, 2017 (JP) 2017-224715

(51) Int. Cl. H01L 21/3065; H01L 21/67; H01L 21/683; H05H 1/46; C23C 16/458

(52) U.S. Cl. CPC H01L 21/3065; H01L 21/67109; C23C 16/458; H05H 1/46; H01L 21/6833

(57) ABSTRACT

A focus ring that surrounds a periphery of a substrate placed on a stage in a processing chamber of a substrate processing apparatus includes a lower surface to contact a peripheral portion of the stage, the lower surface being inclined such that an outer peripheral side becomes lower than an inner peripheral side in a radial direction.

### CROSS-REFERENCE TO RELATED APPLICATION

The present application is based upon and claims priority to Japanese Patent Application No. 2016-254318, filed on Dec. 27, 2016, and the Japanese Patent Application No. 2017-224715, filed on Nov. 22, 2017, the entire contents of which are incorporated herein by reference.

### BACKGROUND OF THE INVENTION

### 1. Field of the Invention

The disclosures herein generally relate to a focus ring and a substrate processing apparatus.

### 2. Description of the Related Art

In a processing chamber of a substrate processing apparatus, a focus ring is disposed to surround a periphery of a substrate placed on an electrostatic chuck. When plasma processing is performed in the processing chamber, the focus ring converges plasma onto the surface of a wafer W so as to improve the efficiency of the plasma processing.

Generally, the focus ring is formed of Si (silicon) and the lower surface is controlled in a horizontal state with no inclination. In recent years, in order to extend the lifetime of the focus ring, materials having higher stiffness such as SiC (silicon carbide) as a typical example have been used for the focus ring.

A heat transfer gas such as He (helium) is supplied to the lower surface of the focus ring disposed at a peripheral portion of the electrostatic chuck. This allows the temperature of the focus ring to be controlled. In Patent Document 1, in order to suppress an increase in an amount of heat transfer gas leaking from a gap between the focus ring and the electrostatic chuck (leakage amount), it is proposed that the focus ring be electrostatically attracted when a wafer is loaded/unloaded and also when a wafer-less dry cleaning (WLDC) is performed.

The electrostatic chuck is fixed on an outer peripheral side of a stage by screws. Therefore, the peripheral portion of the electrostatic chuck is configured to be lower than the central portion of the electrostatic chuck: In a case where the focus ring is formed of Si, the focus ring fits the inclination of the electrostatic chuck because Si is a softer material than Sic. This allows the gap between the focus ring and the electrostatic chuck to be narrowed, preventing a heat transfer gas from leaking.

However, in a case where the focus ring is formed of SiC, the gap between the focus ring and the electrostatic chuck does not narrow because SiC is harder than Si. This poses a problem in that the leakage of a heat transfer gas becomes significant.

### RELATED-ART DOCUMENTS

### Patent Documents

[Patent Document 1] Japanese Laid-Open Patent Publication No. 2016-122740
[Patent Document 2] Japanese Laid-Open Patent Publication No. 2016-225588

### SUMMARY OF THE INVENTION

It is an object of one aspect of the present invention to reduce the leakage of a heat transfer gas.

According to an aspect of at least one embodiment, a focus ring that surrounds a periphery of a substrate placed on a stage in a processing chamber of a substrate processing apparatus includes a lower surface to contact a peripheral portion of the stage, the lower surface being inclined such that an outer peripheral side becomes lower than an inner peripheral side in a radial direction.

According to another aspect of the embodiment, a focus ring that surrounds a periphery of a substrate placed on a stage in a processing chamber of a substrate processing apparatus includes a first flat portion, and a second flat portion, an upper surface of the second flat portion being lower than an upper surface of the first flat portion, wherein the first flat portion is disposed closer to the substrate than the second flat portion to surround the periphery of the substrate, and has a width equal to or greater than a thickness of a sheath.

According to another aspect of the embodiment, a substrate processing apparatus includes a stage disposed in a processing chamber, an electrostatic chuck provided as an upper portion of the stage, a first attraction electrode disposed in a central portion of the electrostatic chuck, a second attraction electrode disposed in a peripheral portion of the electrostatic chuck, and a focus ring that surrounds a periphery of a substrate placed on the electrostatic chuck, wherein a lower surface of the focus ring includes an inclined portion that is inclined from a predetermined range in a direction conforming to an inclination of the peripheral portion of the electrostatic chuck.

Other objects and further features of the present invention will be apparent from the following detailed description when read in conjunction with the accompanying drawings.

### BRIEF DESCRIPTION OF THE DRAWINGS

FIG. 1 is a drawing illustrating an example of a substrate processing apparatus according to an embodiment;

FIG. 2 is a drawing illustrating an example of a shape of a lower surface of a focus ring according to an embodiment;

FIG. 3 is a drawing illustrating an example of deflection of the electrostatic chuck according to an embodiment;

FIG. 4 is a drawing illustrating an example of an amount of the deflection of the electrostatic chuck according to an embodiment;

FIG. 5 is a drawing illustrating an example of conditions under which an amount of a heat transfer gas leaking from the focus ring is measured according to an embodiment;

FIG. 6 is a drawing illustrating examples of an amount of a heat transfer gas leaking from the focus ring according to an embodiment;

FIG. 7 is a drawing illustrating examples of materials and physical property values of the focus ring according to an embodiment and;

FIGS. 8A and 8B are drawings illustrating examples of uniformity of temperature of the focus ring according to an embodiment;

FIGS. 9A through 9D are drawings illustrating other examples of the focus ring according to an embodiment;

FIGS. 10A and 10B are drawings illustrating an example of a change in an etching rate and tilting when a focus ring becomes consumed.

FIG. 11 is a drawing illustrating an example of an amount of a heat transfer gas leaking from the focus ring according to an embodiment;

FIGS. 12A and 12B are drawings illustrating examples of a focus ring according to variation 1 of an embodiment; and

FIGS. 13A and 13B are drawings illustrating examples of a focus ring according to variation 2 of an embodiment; and

### DESCRIPTION OF THE PREFERRED EMBODIMENTS

In the following, embodiments of the present invention will be described with reference to the accompanying drawings. In the specification and drawings, elements having substantially the same configurations are referred to by the same numerals and a duplicate description thereof will be omitted.

### [General Arrangement of Substrate Processing Apparatus]

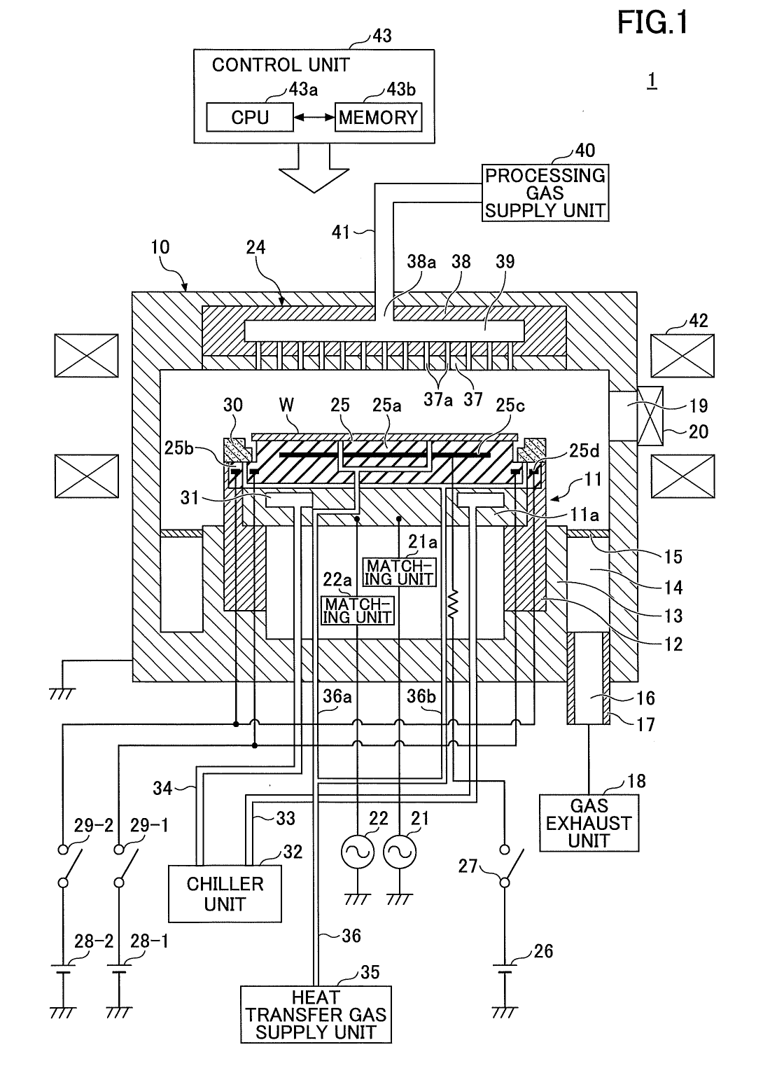

FIG. 1 is a cross-sectional view illustrating a schematic configuration of a substrate processing apparatus 1 according to an embodiment. In the present embodiment, an example in which the substrate processing apparatus 1 disclosed herein is a reactive ion etching (RIE) substrate processing apparatus will be described. However, the substrate processing apparatus 1 may be applied to apparatuses such as a plasma etching apparatus and a plasma-enhanced chemical vapor deposition (PECVD) apparatus that use surface wave plasma.

The substrate processing apparatus 1 includes a cylindrical processing chamber 10 made of metal, for example, aluminum or stainless steel. In the processing chamber, plasma processing such as plasma etching and plasma-enhanced chemical vapor deposition (PECVD) is performed. The processing chamber 10 is grounded.

Provided in the processing chamber 10 is a circular-shaped stage (lower electrode) 11 on which a wafer W, serving as a processing object (substrate), is placed. The stage 11 includes a base 11a and includes an electrostatic chuck 25 on the base 11a. The base 11a is made of aluminum, for example. Also, the base 11a is supported, through an insulating cylindrical support member 12, by a cylindrical support portion 13 extending vertically upward from the bottom of the processing chamber 10.

An exhaust passage 14 is formed between a sidewall of the processing chamber 10 and the cylindrical support portion 13. An annular baffle plate 15 is disposed at an inlet or in a midsection of the exhaust passage 14, and also an exhaust port 16 is disposed at the bottom of the exhaust passage 14. A gas exhaust unit 18 is coupled to the exhaust port 16 through an exhaust pipe 17. The gas exhaust unit 18 includes a vacuum pump and reduces a pressure in a processing space of the processing chamber 10 to a predetermined degree of vacuum. Also, the exhaust pipe 17 includes an automatic pressure control (hereinafter referred to as “APC”) valve, which is a variable butterfly valve. The APC valve automatically controls the pressure in the processing chamber 10. Further, a gate valve 20 configured to open and close a loading/unloading port 19 for the wafer W is installed on the sidewall of the processing chamber 10.

A first high frequency power supply 21 for plasma generation and RIE is electrically connected to the stage 11 through a matching unit 21a. The first high frequency power supply 21 supplies power having a predetermined first high frequency, for example, 40 MHz, to the stage 11.

A second high frequency power supply 22 for bias application is electrically connected to the stage 11 through a matching unit 22a. The second high frequency power supply 22 supplies power having a second high frequency that is lower than the first high frequency, for example, 3 MHz, to the stage 11.

Also, a gas shower head 24 serving as an upper electrode of a ground potential, which will be described later, is disposed in a ceiling portion of the processing chamber 10. Accordingly, a high frequency voltage from the first high frequency power supply 21 is applied between the stage 11 and the gas shower head 24.

The electrostatic chuck 25 for attracting the wafer W thereon by an electrostatic attractive force is provided as an upper portion of the stage 11. The electrostatic chuck 25 includes a circular-shaped central portion 25a on which the wafer W is placed and an annular peripheral portion 25b. The height of the central portion 25a is higher than the height of the peripheral portion 25b. A focus ring surrounding the periphery of the substrate is placed on the upper surface of the peripheral portion 25b.

Further, the central portion 25a is formed by sandwiching an electrode plate 25c formed of a conductive film between a pair of dielectric films. The peripheral portion 25b is formed by sandwiching an electrode plate 25d formed of a conductive film between a pair of dielectric films. A direct current power supply 26 is electrically connected to the electrode plate 25c via a switch 27. Direct current power supplies 28-1 and 28-2 are electrically connected to the electrode plate 25d via switches 29-1 and 29-2. Further, the electrostatic chuck 25 attracts and holds the wafer W on the electrostatic chuck 25 by an electrostatic force such as a Coulomb force generated by the DC voltage applied from the direct current power supply 26 to the electrode plate 25c. Also, the electrostatic chuck 25 attracts and holds the focus ring 30 on the electrostatic chuck 25 by an electrostatic force such as a Coulomb force generated by the DC voltage applied from the direct current power supplies 28-1 and 28-2 to the electrode plate 25d. The electrode plate 25c is an example of a first attraction electrode provided in the central portion 25a of the electrostatic chuck 25. The electrode plate 25d is an example of a second attraction electrode provided in the peripheral portion 25b of the electrostatic chuck 25.

In the stage 11, an annular coolant path extending, for example, in a circumferential direction is provided. A coolant, for example, cooling water at a predetermined temperature is supplied from a chiller unit 32 through pipes 33 and 34 into the coolant path 31 for circulation. A processing temperature of the wafer W placed on the electrostatic chuck 25 is controlled by the temperature of the coolant.

Moreover, a heat transfer gas supply unit 35 is coupled to the electrostatic chuck 25 through a gas supply line 36. The gas supply line 36 is branched into a wafer side line 36a extending to the central portion 25a of the electrostatic chuck 25 and a focus ring side line 36b extending to the peripheral portion 25b of the electrostatic chuck 25.

The heat transfer gas supply unit 35 supplies a heat transfer gas to a space formed between the central portion 25a of the electrostatic chuck 25 and the wafer W through the wafer side line 36a. Also, the heat transfer gas supply unit 35 supplies a heat transfer gas to a space formed between the peripheral portion 25b of the electrostatic chuck 25 and the focus ring 30 through the focus ring side line 36b. As the heat transfer gas, a thermally conductive gas such as He gas is suitably used.

The gas shower head 24 disposed in the ceiling portion includes an electrode plate 37 on its lower surface and an electrode support 38 that detachably supports the electrode plate 37. The electrode plate 37 includes a plurality of gas vent holes 37a. Also, a buffer space 39 is provided inside the electrode support 38. A gas supply pipe 41 extending from a processing gas supply unit 40 is coupled to a gas inlet 38a of the buffer space 39. Further, a magnet 42 extending annularly or concentrically is provided around the processing chamber 10.

The components of the substrate processing apparatus 1 are coupled to a control unit 43. The control unit 43 controls the components of the substrate processing apparatus 1. The components include the gas exhaust unit 18, the first high frequency power supply 21, the second high frequency power supply 22, the switches 27, 29-1, and 29-2 for the electrostatic chuck, the direct current power supplies 26, 28-1, and 28-2, the chiller unit 32, the heat transfer gas supply unit 35, and the processing gas supply unit 40.

The control unit 43 includes a CPU 43a and a memory 43b (storage). By reading and executing a program and a processing recipe stored in the memory 43b, a desired substrate process is controlled in the substrate processing apparatus 1. Further, in accordance with the substrate process, the control unit 43 controls an electrostatic attraction process for electrostatically attracting the focus ring 30 and controls a heat transfer gas supplying process for supplying a heat transfer gas.

In the processing chamber 10 of the substrate processing apparatus 1, a horizontal magnetic field oriented in one direction is generated by the magnet 42. In addition, a vertical radio frequency (RF) magnetic field is generated by the high frequency power supplied between the stage and the gas shower head 24. Accordingly, a magnetron discharge is generated through a processing gas in the processing chamber 10. As a result, high-density plasma is generated from the processing gas near the surface of the stage 11.

In the substrate processing apparatus 1, in order to perform dry etching processing, the gate valve 20 is opened. Subsequently, the wafer W as the processing object is loaded in the processing chamber 10 and placed on the electrostatic chuck 25. The processing gas supply unit 40 introduces a processing gas (for example, a gaseous mixture of C₄F₈ gas, O₂ gas, and Ar gas mixed at a predetermined flow rate ratio) into the processing chamber 10 at a predetermined flow rate and a predetermined flow rate ratio. The pressure in the processing chamber is set to a predetermined value by the gas exhaust unit 18 and the like. Further, the first high frequency power supply 21 and the second high frequency power supply 22 supply a high frequency power to the stage 11. The direct current power supply 26 applies a DC voltage to the electrode plate 25c of the electrostatic chuck 25. Accordingly, the wafer W is attracted to the electrostatic chuck 25. A heat transfer gas is supplied to the bottom side of the wafer W and the bottom side of the focus ring 30. The processing gas injected from the gas shower head 24 is converted into plasma and the surface of the wafer W is subjected to predetermined plasma processing by radicals and ions in the plasma.

### [Inclined Portion of Focus Ring]

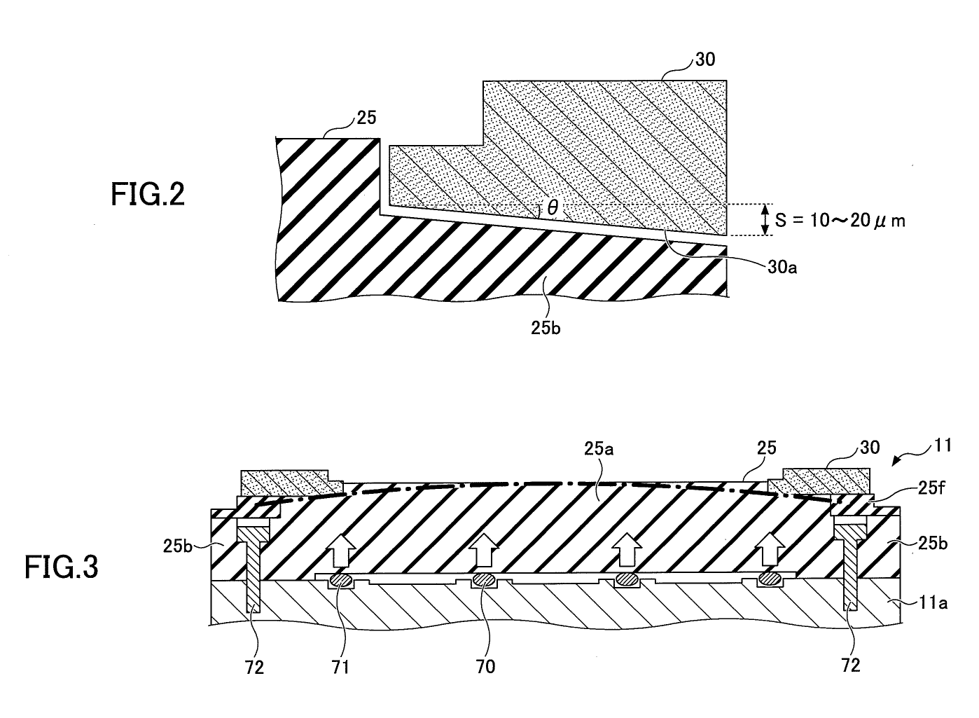

Next, referring to FIG. 2, a configuration of the focus ring 30 of the present embodiment will be described. The lower surface of the focus ring 30 of the present embodiment includes an inclined portion 30a that is inclined from a predetermined range in a direction conforming to the inclination of the peripheral portion 25b of the electrostatic chuck 25 when disposed facing the peripheral portion 25b of the electrostatic chuck 25.

As illustrated in FIG. 3, the peripheral portion 25b of the electrostatic chuck 25 is fixed to the base 11a by screws 72. The focus ring 30 is placed on the peripheral portion 25b through a portion 25f of the electrostatic chuck 25.

O-rings 70 on an inner peripheral side and O-rings 71 on an outer peripheral side are placed between the base 11a and the electrostatic chuck 25 at positions inside the portions fixed by the screws 72. Accordingly, reaction forces exerted by the O-rings 70 on the central portion 25a of the electrostatic chuck 25, reaction forces exerted by the O-rings 71 on the peripheral portion 25b, and the fixation by the screws 72 cause the central portion 25a of the electrostatic chuck 25 to be raised higher than the peripheral portion 25b. Therefore, the electrostatic chuck 25 is formed into a shape in which the peripheral portion 25b is lower than the central portion 25a.

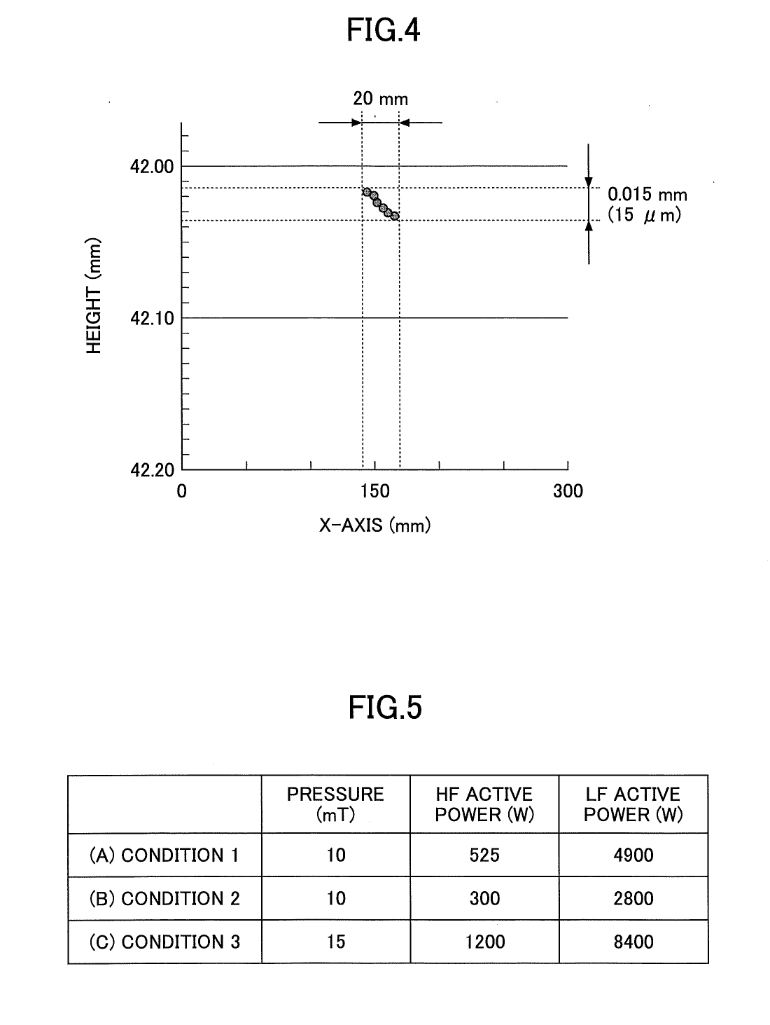

FIG. 4 illustrates an amount of the deflection of the electrostatic chuck 25 according to an embodiment. FIG. 4 illustrates the deflection of the focus ring attracting surface (peripheral portion 25b) of the electrostatic chuck 25. As seen from FIG. 4, the focus ring attracting surface deflects.

In a case where the focus ring 30 of the present embodiment is formed of SiC, the focus ring does not fit the inclination of the peripheral portion 25b of the electrostatic chuck 25 because SiC is harder than Si. Therefore, unless the inclination is provided on the bottom side of the focus ring 30, a gap between the focus ring 30 and the peripheral portion 25b of the electrostatic chuck 25 cannot be narrowed, causing a heat transfer gas to leak.

Therefore, the focus ring 30 of the present embodiment includes the inclined portion 30a that is inclined in a direction in which the peripheral portion 25b of the electrostatic chuck 25 is inclined. This allows the gap between the focus ring 30 and the electrostatic chuck 25 to be narrowed, reducing the amount of heat transfer gas leakage.

### [Inclination of Focus Ring]

With respect to a value of 38 mm representing a width+α in the radial direction for the part of the focus ring 30 that is disposed above the electrostatic chuck 25, the lower surface of the focus ring 30 is inclined from a range of 10 μm to 20 μm at the outer peripheral side as indicated by S of FIG. 2. Namely, when the inclination (difference in level) is from 10 μm, the inclination angle θ with respect to the horizontal direction becomes approximately 0.03° and when the inclination is from 20 μm, the inclination angle becomes approximately 0.06°. The range defines the side opposite the inclination angle. Namely, the inclination angle with respect to the horizontal direction is preferably in a range of 0.03° to 0.06°. The reasons why this range of values is preferred will be described below.

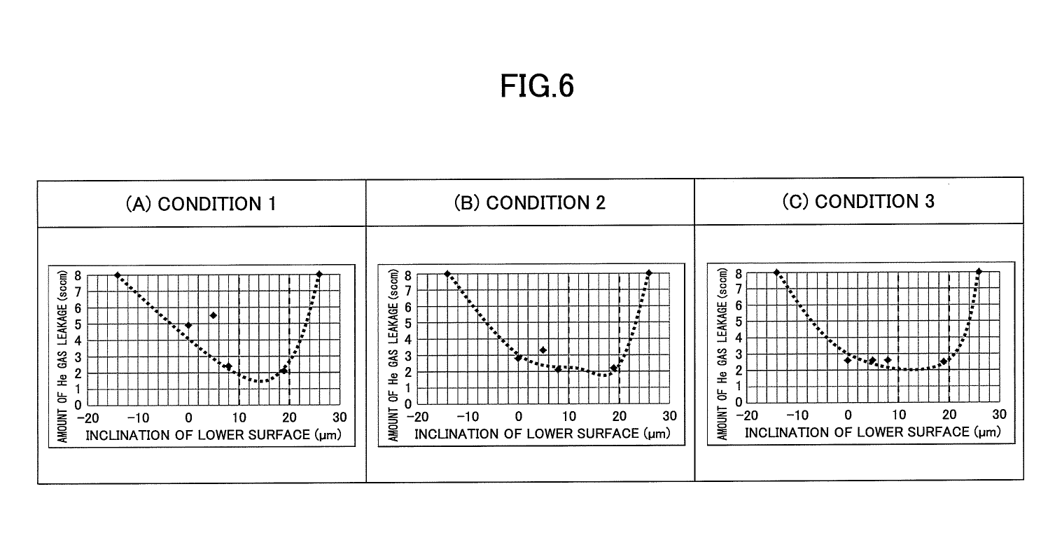

An experiment for measuring an amount of heat transfer gas leakage was performed by changing the angles of the inclination of the lower surface of the focus ring 30. FIG. 5 illustrates conditions of the experiment and FIG. 6 illustrates results of the experiment. As illustrated in FIG. 5, the experiment for measuring an amount of heat transfer gas leakage was performed under three different conditions: (a) condition 1, (b) condition 2, and (b) condition 3.

In (a) condition 1, the pressure for the plasma processing is 10 mTorr (1.33 Pa), the active power of the first high frequency power is 525 W, and the active power of the second high frequency power is 4900 W.

In (b) condition 2, the pressure for the plasma processing is 10 mTorr (1.33 Pa), the active power of the first high frequency power is 300 W, and the active power of the second high frequency power is 2800 W.

In (c) condition 3, the pressure for the plasma processing is 15 mTorr (2.00 Pa) the active power of the first high frequency power is 1200 W, and the active power of the second high frequency power is 8400 W.

While the plasma processing using the substrate processing apparatus 1 is performed under the respective conditions, He gas was supplied as a heat transfer gas. Also, the experiment was performed by using a single electrostatic chuck 25. FIG. 6 illustrates the results of the experiment performed by using the single electrostatic chuck 25 under the conditions (a) through (c). In the etching processing, when a change was made in the inclination of the lower surface of the focus ring 30 as indicated on the horizontal axis in FIG. 6, the amount of the leakage of the He gas changed accordingly as indicated on a vertical axis in all the conditions (a) through (c) in FIG. 6.

When a value indicated on the horizontal axis is a negative value, the lower surface of the focus ring 30 is inclined such that the inner peripheral side becomes lower than the outer peripheral side. When a value indicated on the horizontal axis is a positive value, the lower surface of the focus ring 30 is inclined such that the outer peripheral side becomes lower than the inner peripheral side, as indicated by S in FIG. 2 from a range of 10 μm to 20 μm.

The results of the experiment indicate that, in all of the condition 1, the condition 2, and the condition 3 of FIG. 6, an amount of heat transfer gas (He) leakage becomes the smallest when the outer peripheral side is lower than the inner peripheral side from a range of 10 μm to 20 μm. Namely, the lower surface of the focus ring 30 is preferably inclined such that the outer peripheral side of the focus ring 30 becomes lower than the inner peripheral side of the focus ring 30 in the radial direction. Also, the lower surface of the focus ring 30 is preferably inclined in the range of 10 μm to 20 μm with respect to the above-described width of the focus ring 30.

When the inclination is less than the lower limit (10 μm) of the above-described range, it becomes difficult to prevent a heat transfer gas from leaking from the outer peripheral side of the focus ring 30. Conversely, when the inclination exceeds the upper limit (20 μm) of the above-described range, it becomes difficult to prevent a heat transfer gas from leaking from the inner peripheral side of the focus ring 30. Therefore, making the inclination of the outer peripheral side of the focus ring 30 lower than the inner peripheral side from the range of 10 μm to 20 μm can prevent a heat transfer gas from leaking from the lower surface of the focus ring 30.

### [Material of Focus Ring]

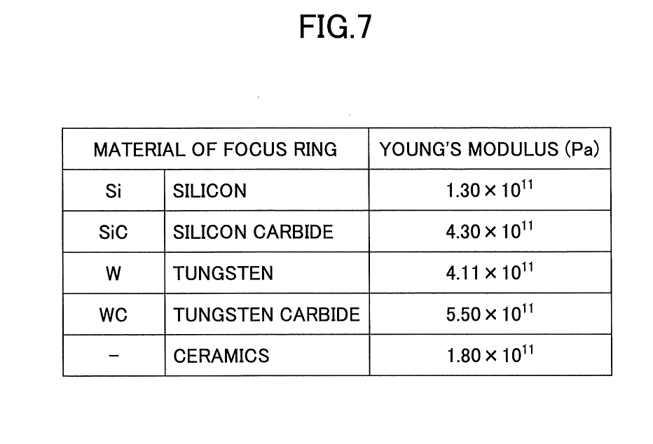

As illustrated in FIG. 7, the focus ring 30 may be formed of any one of SiC (silicon carbide), W (tungsten), WC (tungsten carbide), and ceramics, which are harder than Si (silicon) whose Young's modulus is 1.30×10¹¹. In addition, the focus ring 30 may be formed of not only a material harder than Si, but also Si or SiO₂.

The Young's modulus of SiC (silicon carbide) is 4.30×10¹¹ (Pa), the Young's modulus of W (tungsten) is 4.11×10¹¹ (Pa), and the Young's modulus of WC (tungsten carbide) is 5.50×10¹¹ (Pa). Further, the Young's modulus of silicon carbide ceramics is approximately 1.80×10¹¹ (Pa).

The focus ring 30 of the present embodiment is preferably made of a material whose Young's modulus is 5.0×10¹⁰ to 1.0×10¹² (Pa), including the Young's modulus of Si, SiO₂, SiC, W, WC, and ceramics.

In particular, the focus ring 30 formed of SiC (silicon carbide) is preferable because characteristics such as a resistance to plasma processing are similar to those of the focus ring 30 formed of Si (silicon) conventionally used.

### [Temperature Control of Focus Ring]

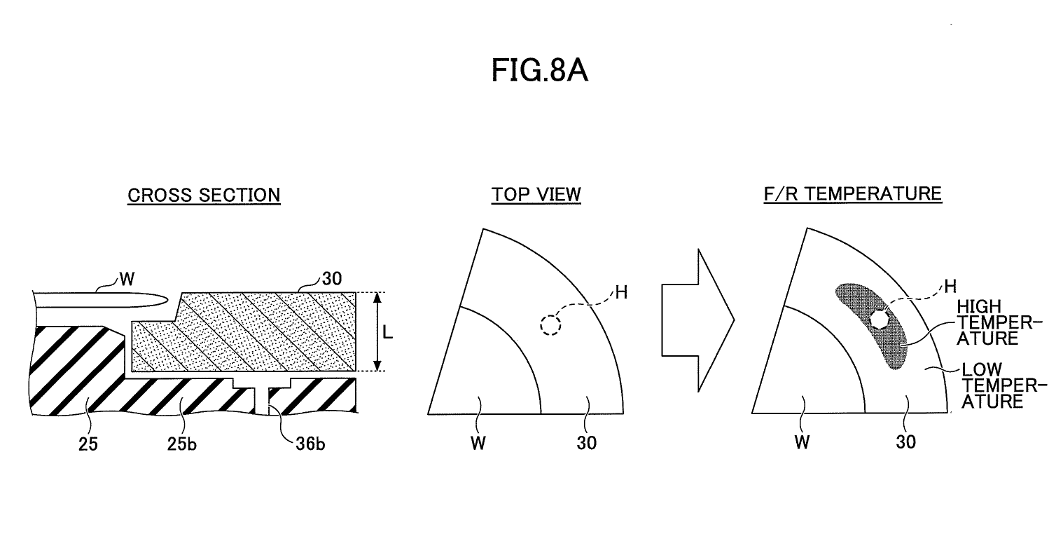

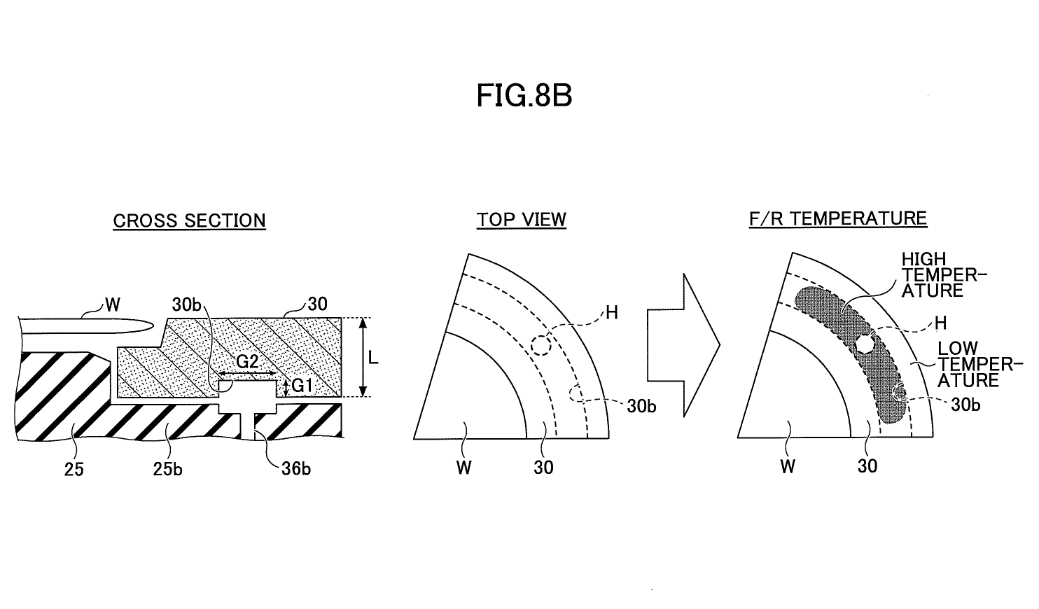

Next, referring to FIGS. 8A and 8B, a shape of the bottom side of the focus ring 30 and temperature control will be described. In an example of FIG. 8A, as illustrated in the cross-sectional view, the bottom side of the focus ring 30 does not have an inclined portion and is flat in shape. In an example of FIG. 8B, as illustrated in the cross-sectional view, the bottom side of the focus ring 30 does not have an inclined portion and an annular groove 30b is formed above the focus ring side line 36b of the electrostatic chuck 25. The focus ring side line 36b supplies a heat transfer gas.

As illustrated in a top view of FIG. 8A and a top view of FIG. 8B, a heat transfer gas is introduced from a gas hole H located at an end of the focus ring side line 36b to the bottom side of the focus ring 30. Accordingly, in the example illustrated in FIG. 8B, because the heat transfer gas is diffused in a space inside the groove 30b, the leakage of the heat transfer gas can be further reduced as compared to the example illustrated in FIG. 8B, allowing the temperature of the focus ring 30 to be favorably controlled and the uniformity of the temperature distribution to be ensured.

The results of the experiment are not results obtained by measuring the temperature of the focus ring 30 directly. In the experiment, the uniformity of the temperature of the focus ring 30 was determined based on a variation (nonuniformity) in the distribution of reaction products adhering to the focus ring 30. When the temperature distribution is uneven, a variation in the distribution of reaction products adhering to the focus ring 30 becomes apparent. Therefore, in the experiment, the uniformity of the temperature was determined based on the presence or absence of a variation in the distribution of reaction products.

Further, in the experiment, a thickness L of the focus ring 30 was 3.35 mm. Also, for a depth G1 and a width G2, the following four patterns were set in the experiment.

(1) Depth G1 is 0.5 mm, width G2 is 2.2 mm
(2) Depth G1 is 0.1 mm, width G2 is 2.2 mm
(3) Depth G1 is 0.1 mm, width G2 is 5.6 mm
(4) Depth G1 is 0.05 mm, width G2 is 5.6 mm
In all the patterns, when the groove 30b located on the bottom side of the focus ring 30 is provided in a position facing the gas hole H through which a heat transfer gas is supplied, the uniformity of the temperature distribution of the focus ring 30 can be ensured as compared to the example in FIG. 8A in which no groove is provided.

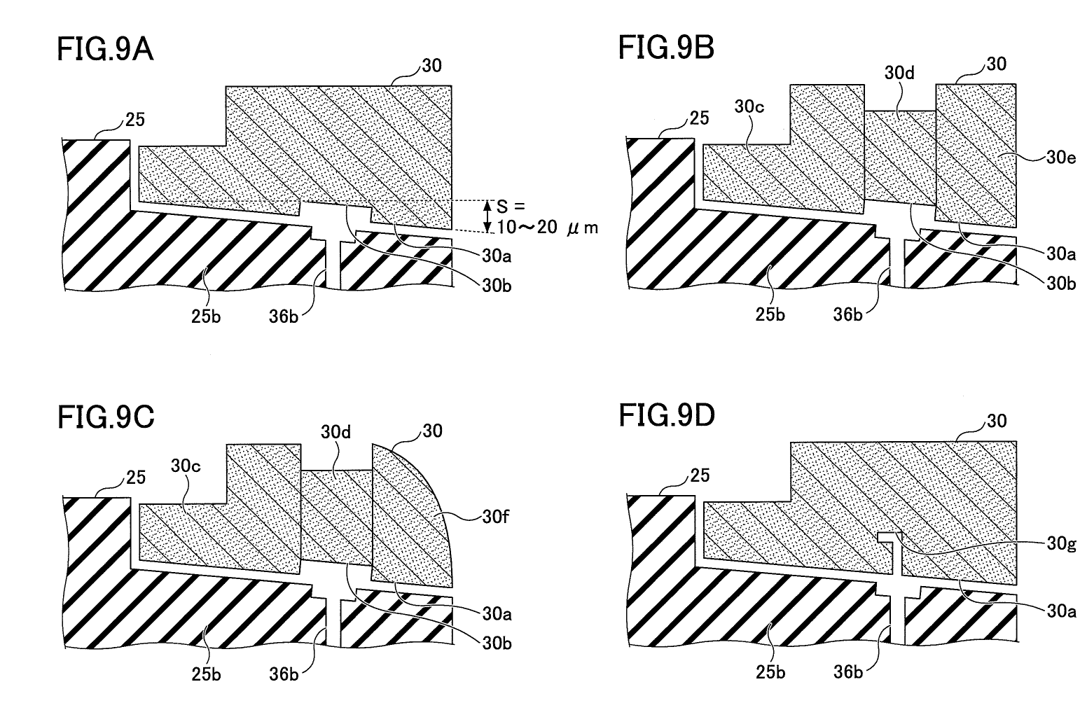

Therefore, as illustrated in FIG. 9A, in the focus ring 30 of the present embodiment, the lower surface of the focus ring 30 includes the inclined portion 30a that has an inclination from 10 μm to 20 μm in a direction conforming to the inclination of the peripheral portion 25b of the electrostatic chuck 25. Further, the groove 30b may be formed on the inclined surface of the focus ring 30. The groove 30b formed may be an annular groove extending in a circumferential direction or may be a plurality of non-annular recesses formed above a plurality of gas holes H through which a heat transfer gas is supplied.

As illustrated in FIG. 9B, the focus ring 30 of the present embodiment includes three portions 30c, 30d, and 30e. The groove 30b may be formed by making the length of the central portion 30d in the height direction smaller than the length of the side portions 30c and 30e. Namely, the groove 30b is formed by a level difference between the portions 30c with 30e and the portion 30d. Also, by providing the groove 30b of the focus ring 30 of the present embodiment in a position facing the gas hole H through which a heat transfer gas is supplied, the leakage of the heat transfer gas can be reduced and the uniformity of the temperature distribution of the focus ring 30 can be ensured.

The focus ring 30 of the present embodiment may include three portions 30c, 30d, and 30f illustrated in FIG. 9C. In this case, similarly to FIG. 9B, the groove 30b may be formed by making the length of the central portion 30d in the height direction smaller than the length of the side portions 30c and 30f. A shape of the outermost peripheral portion of the focus ring 30 may be provided in a rectangular shape as illustrated by the portion 30e of FIG. 9B or may be provided in a rounded shape as illustrated by the portion 30f of FIG. 9C.

In place of the groove 30b illustrated in FIGS. 9A through 9C, a groove 30g bent in the focus ring 30 may be provided as illustrated in FIG. 9D. The groove 30g may bend inward, may bend outward, or may bend to both sides.

As illustrated in FIGS. 9A through 9D, by causing the lower surface of the focus ring 30 to be inclined from a predetermined range and also providing the groove 30b or the groove 30g, the leakage of a heat transfer gas can be reduced and the uniformity of the temperature distribution can be ensured. At least a portion of a groove formed on the lower surface of the focus ring 30 is preferably provided at a position facing the gas hole H through which a heat transfer gas is supplied.

As described above, according to the focus ring 30 of the present embodiment, the lower surface includes the inclined portion 30a that is inclined from a predetermined range. Accordingly, the focus ring 30 fits the inclination of the electrostatic chuck 25 and the leakage of a heat transfer gas can be reduced.

Further, by providing a groove on the inclined portion 30a, the leakage of a heat transfer gas can be further reduced. Moreover, the heat transfer gas supplied to the lower surface of the focus ring 30 can be easily diffused, ensuring the uniformity of the temperature distribution of the focus ring 30.

### [Variation 1]

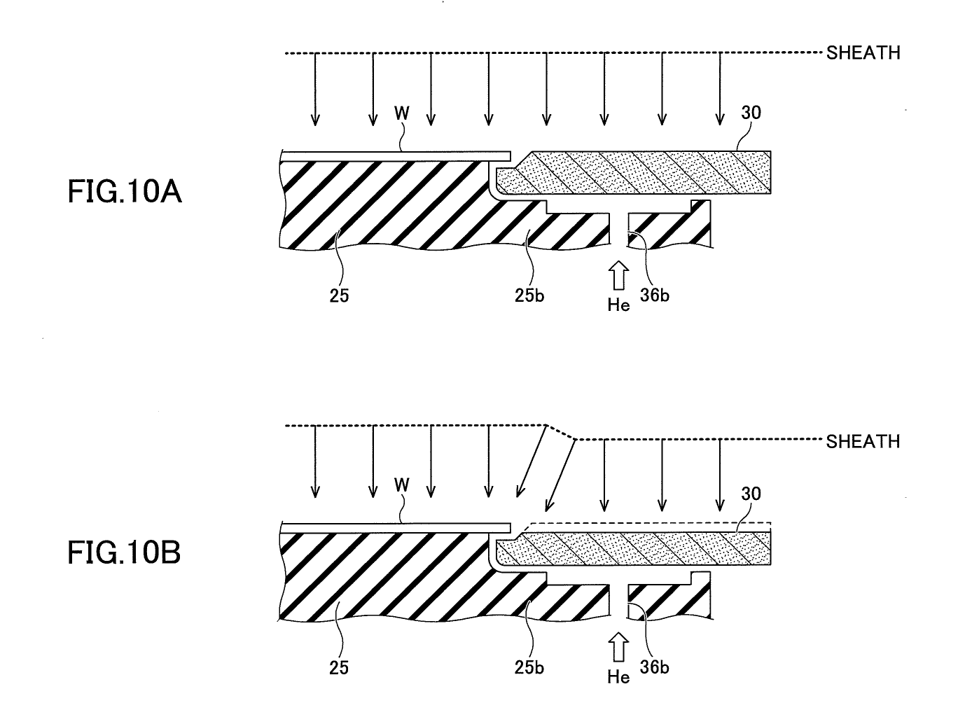

Before a configuration of a focus ring 30 according to variation 1 of the embodiment is described, sheath conditions will be described with reference to FIGS. 10A and 10B.

As illustrated in FIG. 10A, when the focus ring 30 is assumed to be new, an upper surface of the focus ring 30 and an upper surface of the wafer W are designed to be at the same height. In such a case, during plasma processing, a sheath above the wafer W and a sheath above the focus ring have the same thickness. In this state, an incident angle of ions to the wafer W and the focus ring 30 is vertical. Therefore, an etching profile such as a hole formed on the wafer W becomes a vertical profile, and no tilt (a tilt in the etching profile) is caused. Also, an etching rate becomes uniform over the entire surface of the wafer W.

However, the focus ring 30 is exposed to plasma during the plasma processing, and thus the focus ring 30 becomes consumed. As illustrated in FIG. 10B, the upper surface of the focus ring 30 becomes lower than the upper surface of the wafer W. Accordingly, the sheath above the focus ring 30 becomes lower than the sheath above the wafer W.

As a result, at an edge of the wafer W where a difference in level is formed in the sheath, the incident angle of ions becomes oblique and a tilt in the etching profile is caused. Also, the etching rate at the edge of the wafer W changes and the etching rate over the entire surface of the wafer W becomes non-uniform.

As described above, in a case where the focus ring 30 illustrated in FIG. 10A is formed of SiC, it is difficult for the focus ring 30 to fit the inclination of the electrostatic chuck 25 as compared to when the focus ring is formed of Si because SiC is harder than Si. Therefore, there is a problem in that the amount of a heat-transfer gas such as He gas supplied to the bottom side of the focus ring leaking from a gap between the focus ring and the electrostatic chuck increases.

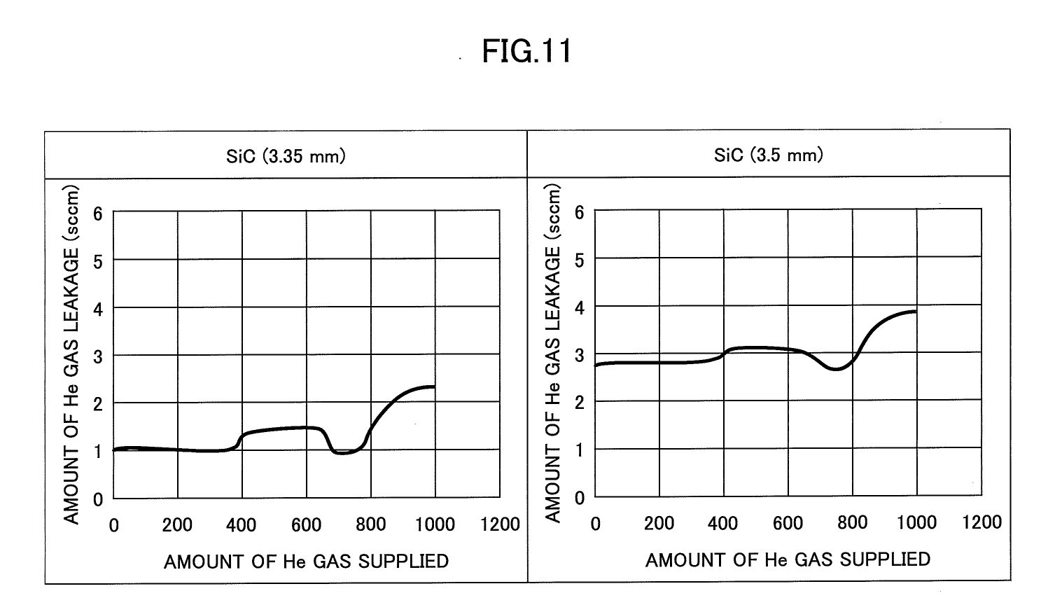

FIG. 11 illustrates an example of an amount of He gas leakage when the focus ring 30 is formed of SiC. The horizontal axis in FIG. 11 indicates an amount of He gas supplied to the bottom side of the focus ring 30. The vertical axis in FIG. indicates an amount of He gas leaking from the gap between the focus ring and the electrostatic chuck 25. The left side of FIG. 11 illustrates the result when a focus ring 30 formed of SiC and having a thickness of 3.35 mm was used. The right side of FIG. 11 illustrates the result when a focus ring 30 formed of SiC and having a thickness of 3.5 mm was used.

As indicated in FIG. 11, approximately 2 sccm of He gas leaked when the focus ring 30 having a thickness of 3.35 mm was used. Further, approximately 3.5 sccm of He gas leaked when the focus ring 30 having a thickness of 3.5 mm was used. Namely, when the focus ring is formed of a material whose Young's modulus is 5.0×10¹⁰ to 1.0×10¹² (Pa) such as SiC, an amount of He gas leaking from the gap changes depending on the thickness of the focus ring.

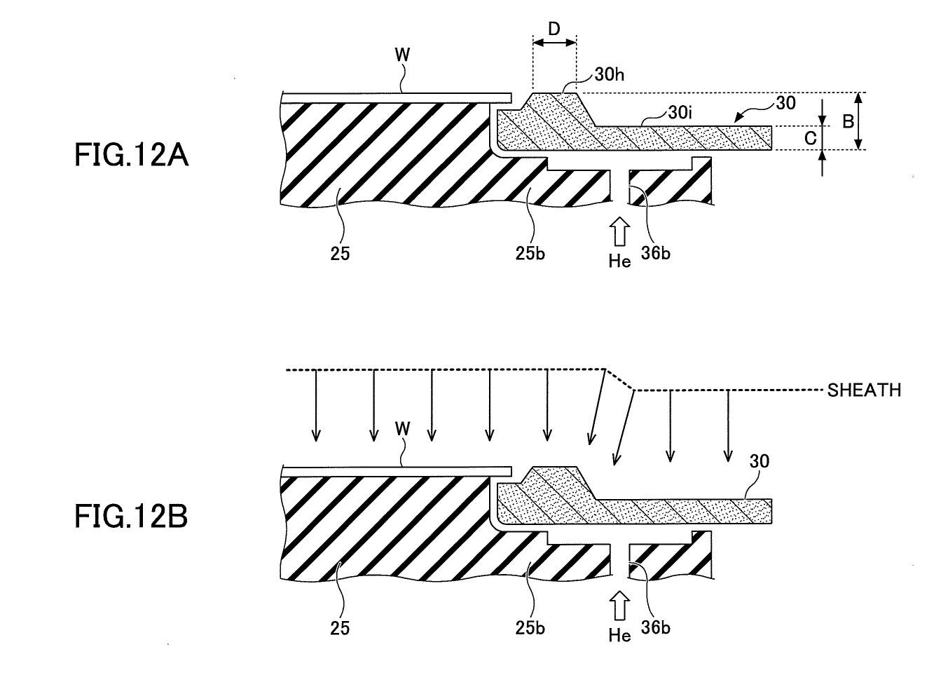

In light of the above, in variation 1 of the embodiment, a shape and a thickness of the focus ring 30 will be devised as illustrated in FIG. 12A. To be more specific, the focus ring 30 of variation 1 includes a first flat portion 30h and a second flat portion 30i that is thinner than the first flat portion 30h. The first flat portion 30h is disposed closer to the wafer W than the second flat portion 30i to surround a periphery of the wafer W. The upper surface of the second flat portion 30i is lower than the upper surface of the first flat portion 30h and the lower surface of the focus ring 30 is flat.

According to such a configuration, by providing the focus ring 30 with the second flat portion 30i that is thinner than the first flat portion 30h, the stiffness of the outer peripheral side of the focus ring 30 decreases. This makes it possible to reduce the amount of a heat-transfer gas leaking from the gap between the bottom side of the focus ring 30 and the electrostatic chuck 25.

Further, the upper surface of focus ring 30 of variation 1 is provided with the first flat portion 30h that is formed to surround the periphery of the wafer W. The upper surface of the first flat portion 30h is higher than the upper surface of the second flat portion 30i. This can prevent a tilt in the etching profile.

To be more specific, a width D of the first flat portion 30h is preferably formed to be equal to or greater than the thickness of the sheath. In general, the thickness of the sheath is in a range of 5 mm to 10 mm, although the thickness of the sheath changes depending on, for example, the DC voltage applied from a direct current power supply. Therefore, the width of the first flat portion 30h is preferably in a range of 5 mm to 10 mm or is preferably 10 mm or more.

The width D of the first flat portion 30h that is equal to or greater than the thickness of the sheath can prevent the sheath from being formed obliquely at the edge of the wafer W. Namely, because the first flat portion 30h of the present variation has the width D that is equal to or greater than the thickness of the sheath, a difference in level is formed in the sheath at a position outward from the edge of the wafer W by a distance corresponding to the width D as illustrated in FIG. 12B. This prevents a tilt in the etching profile at the edge of the wafer W. Also, the uniformity of the etching rate can be enhanced.

A height B of the first flat portion 30h of the focus ring 30 illustrated in FIG. 12A is determined based on the process conditions. The height B is determined such that the upper surface of the first flat portion 30h and the upper surface of the wafer W are preferably at the same or approximately the same height.

A height C of the second flat portion 30i of the focus ring 30 is determined based on an inclination allowance of the focus ring 30, an inclination allowance of the electrostatic chuck 25, and physical property values (such as the Young's modulus) of the material of the focus ring 30.

The height C of the second flat portion 30i may be constant or may not be constant. For example, the height C of the second flat portion 30i may be flat or may become gradually lower toward the outer peripheral side. Also, the height C of the central portion of the second flat portion 30i may be lower than the inner side and the outer side. However, the height C of the second flat portion 30i is at least lower than the height B of the first flat portion 30h. Namely, the stiffness of the second flat portion 30i is designed to be lower than the stiffness of the first flat portion 30h.

According to the focus ring 30 of variation 1, by providing the focus ring 30 with the second flat portion 30i that is thinner than the first flat portion 30h, an amount of heat-transfer gas leakage can be reduced. In addition, a tilt in the etching profile at the edge of the wafer W can be prevented while the uniformity of the etching rate can be enhanced.

The focus ring 30 of variation 1 can be applied to the substrate processing apparatus 1 of the above-described embodiment. This allows the amount of heat-transfer gas leakage to be reduced. In addition, even after the focus ring 30 becomes consumed through the plasma processing, a tilt in the etching profile can be prevented while the uniformity of the etching rate can be enhanced.

### [Variation 2]

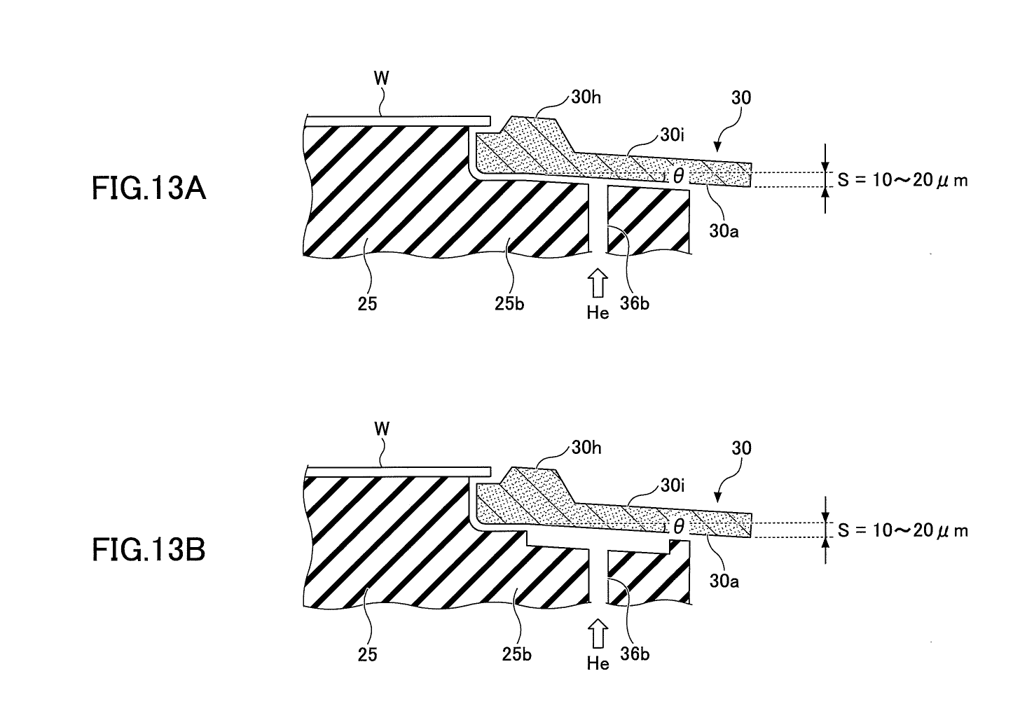

Next, referring to FIGS. 13A and 13B, a focus ring 30 of variation 2 of the embodiment will be described. FIGS. 13A and 13B are drawings illustrating examples of a focus ring 30 according to variation 2 of the embodiment.

The focus ring 30 of variation 2 includes the inclined portion of the lower surface of the above-described focus ring, and includes the upper surface of the focus ring 30 of variation 1. A difference between FIG. 13A and FIG. 13B is that the electrostatic chuck 25 in FIG. 13B has a recessed portion at its heat-transfer gas inlet while the electrostatic chuck 25 in FIG. 12A has a flat surface at its heat-transfer gas inlet.

Namely, the lower surface of the focus ring 30 of variation 2 includes an inclined portion 30a that is inclined from a predetermined range in a direction conforming to the inclination of a peripheral portion 25b of the electrostatic chuck 25 when disposed facing the peripheral portion 25b of the electrostatic chuck 25. The lower surface of the inclined portion 30a of the focus ring 30 is inclined from a range of 10 μm to 20 μm at the outer peripheral side as indicated by S of FIG. 13A. Namely, when the inclination (difference in level) is from 10 μm, the inclination angle θ with respect to the horizontal direction becomes approximately 0.03° and when the inclination is from 20 μm, the inclination angle becomes approximately 0.06°. Namely, the inclination angle with respect to the horizontal direction is preferably in a range of 0.03° to 0.06°.

As illustrated in FIG. 13A and FIG. 13B, the upper surface of the focus ring 30 of variation 2 has the same configuration as the configuration of the focus ring 30 of variation 1, and includes a first flat portion 30h and a second flat portion 30i that is lower than the first flat portion 30h. The first flat portion 30h is disposed closer to the wafer W than the second flat portion 30i to surround the periphery of the wafer W. The width D of the first flat portion 30h is equal to or greater than the thickness of the sheath. The width of the first flat portion 30h is preferably in the range of 5 mm to 10 mm or is preferably 10 mm or more.

According to such a configuration, the focus ring 30 of variation 2 includes the characteristics of the lower surface of the focus ring 30 of the above-described embodiment, and also includes the characteristics of the upper surface of the focus ring 30 of variation 1. Accordingly, the focus ring 30 of variation 2 can further reduce the leakage of a heat-transfer gas. In addition, a tilt in the etching profile can be prevented while the uniformity of the etching rate can be enhanced.

Further, the focus ring 30 of variation 2 can be applied to the substrate processing apparatus 1 of the above-described embodiment. This allows the amount of heat-transfer gas leakage to be reduced. In addition, even after the focus ring 30 is consumed through the plasma processing, a tilt in the etching profile can be prevented while the uniformity of the etching rate can be enhanced.

According to at least one embodiment, the leakage of a heat transfer gas can be reduced.

Although a focus ring and a substrate processing apparatus according to the embodiments have been described above, the focus ring and the substrate processing apparatus of the present invention are not limited to the above-described embodiments. Various variations and modifications may be made without departing from the scope of the present invention. It should be noted that the above-described embodiments may be combined as long as no contradiction occurs.

For example, the present invention may be applied not only to the parallel flat plate type apparatus for applying two frequencies as illustrated in FIG. 1, but also to other substrate processing apparatuses. Examples of such other substrate processing apparatuses include a capacitively coupled plasma (CCP) apparatus, an inductively coupled plasma (ICP) processing apparatus, a substrate processing apparatus using a radial line slot antenna, a helicon wave plasma (HWP) apparatus, an electron cyclotron resonance (ECR) plasma apparatus, and a substrate processing apparatus using surface wave plasma.

Although the semiconductor wafer W has been described herein as an etching substrate, the present invention is not limited thereto. Various substrates used for a liquid crystal display (LCD) and a flat panel display (FPD), a photomask, a CD substrate, a printed circuit board, and the like may be used.

What is claimed is:

1. A focus ring that surrounds a periphery of a substrate placed on a stage in a processing chamber of a substrate processing apparatus, comprising,
a lower surface to contact a peripheral portion of the stage, the lower surface being inclined such that an outer peripheral side becomes lower than an inner peripheral side in a radial direction.

2. The focus ring according to claim 1, wherein the focus ring is formed of a material whose Young's modulus is 5.0×10¹⁰ to 1.0×10¹² (Pa).

3. The focus ring according to claim 1, wherein the focus ring is formed of any one of SiC, Si, SiO₂, W, WC, and ceramics.

4. The focus ring according to claim 1, wherein the lower surface is inclined from a range of 10 μm to 20 μm in the direction conforming to an inclination of the peripheral portion of the stage.

5. The focus ring according to claim 1, wherein a groove is formed on the lower surface.

6. The focus ring according to claim 5, wherein the groove is an annular groove.

7. The focus ring according to claim 5, wherein the groove is a bent groove.

8. A focus ring that surrounds a periphery of a substrate placed on a stage in a processing chamber of a substrate processing apparatus, comprising:
a first flat portion; and
a second flat portion, an upper surface of the second flat portion being lower than an upper surface of the first flat portion,
wherein the first flat portion is disposed closer to the substrate than the second flat portion to surround the periphery of the substrate, and has a width equal to or greater than a thickness of a sheath.

9. The focus ring according to claim 8, further comprising a lower surface to contact a peripheral portion of the stage,
wherein the lower surface includes an inclined portion, the inclined portion being inclined from a predetermined range in a direction conforming to an inclination of the peripheral portion of the stage.

10. The focus ring according to claim 8, wherein the width equal to or greater than the thickness of the sheath is in a range of 5 mm to 10 mm.

11. The focus ring according to claim 8, wherein the first flat portion is at the same or approximately the same height as an upper surface of the substrate.

12. A substrate processing apparatus comprising:
a stage disposed in a processing chamber;
an electrostatic chuck provided as an upper portion of the stage;
a first attraction electrode disposed in a central portion of the electrostatic chuck;
a second attraction electrode disposed in a peripheral portion of the electrostatic chuck; and
a focus ring that surrounds a periphery of a substrate placed on the electrostatic chuck,
wherein a lower surface of the focus ring includes an inclined portion that is inclined from a predetermined range in a direction conforming to an inclination of the peripheral portion of the electrostatic chuck.

13. The substrate processing apparatus according to claim 12, wherein a groove is formed on the lower surface of the focus ring.

14. The substrate processing apparatus according to claim 12, wherein the groove is disposed at a position facing a gas hole located at an end of a heat transfer gas supply line disposed in the substrate processing apparatus.

15. The substrate processing apparatus according to claim 12, wherein an upper surface of the focus ring includes a first flat portion and a second flat portion that is lower than the first flat portion, the first flat portion being disposed closer to the substrate than the second flat portion to surround the periphery of the substrate, and having a width equal to or greater than a thickness of a sheath.
